(19) United States
(12) Patent Application Publication
(10) Pub. No.: US 2011/0220897 A1
(43) Pub. Date: Sep. 15, 2011

(54) ARRAY SUBSTRATE OF LIQUID CRYSTAL DISPLAY AND FABRICATION METHOD THEREOF

(75) Inventor: Young-Chul SHIN, Yongin-city (KR)

(73) Assignee: SAMSUNG MOBILE DISPLAY CO., LTD., Yongin-city (KR)

(21) Appl. No.: 13/034,611

(22) Filed: Feb. 24, 2011

(30) Foreign Application Priority Data
Mar. 10, 2010 (KR) 10-2010-0021261

(51) Int. Cl. H01L 27/15; H01L 21/285; H01L 21/336

(52) U.S. Cl. 257/59; 438/591; 438/156; 257/E21.409; 257/E21.16; 257/E27.121

(57) ABSTRACT

An array substrate of a liquid crystal display and a method of fabrication for the same are disclosed. The method of fabrication includes: forming a gate electrode on a first region of a substrate, where the substrate is divided into first and second regions, forming a lower storage electrode, including a transparent conductive material, on the second region of the substrate, and forming a gate insulating layer on the substrate, where the gate insulating layer includes first, second and third gate insulating sub-layers.

### CROSS-REFERENCE TO RELATED APPLICATIONS

This application claims priority to and the benefit of Korean Patent Application No. 10-2010-0021261, filed on Mar. 10, 2010, in the Korean Intellectual Property Office, the entire content of which is incorporated herein by reference.

### BACKGROUND

1. Field

The present embodiments relate to a liquid crystal display, and more particularly, to an array substrate of a liquid crystal display and a fabrication method thereof.

2. Description of the Related Technology

A liquid crystal display displays an image by adjusting light transmission of a liquid crystal using an electric field. A liquid crystal display generally drives the liquid crystal by controlling an electric field between a pixel electrode that is typically disposed on a lower substrate, an array substrate on which thin film transistors are formed, and a common electrode that is disposed on upper substrate, on which a color filter is formed, to face each other.

A liquid crystal display generally includes a lower substrate and an upper substrate, which face each other, a spacer for maintaining a cell gap between the lower substrate and the upper substrate, and a liquid crystal occupying the cell gap.

The upper substrate typically includes a color filter for expressing colors, a black matrix for preventing light leakage, a common electrode for controlling an electric field, and an orientation film coating to orient the liquid crystal. The lower substrate typically includes a plurality of signal lines and thin film transistors, a pixel electrode connected to the thin film transistors, and an orientation film coating to orient the liquid crystal. In addition, the lower substrate typically further includes a storage capacitor for stably maintaining a pixel voltage signal, charged to the pixel electrode, and stable until a next voltage signal is charged.

The storage capacitor is generally formed by a lower storage electrode, an upper storage electrode, and an insulating layer interposed therebetween. The storage capacitor typically has a large capacitance in order to maintain the pixel voltage signal at a stable level and to be applied to a high definition display. However, when of the distance between the upper and lower storage electrodes is widened in order to increase the capacitance of the storage capacitor, the aperture ratio is proportionally lowered.

### SUMMARY OF CERTAIN INVENTIVE ASPECTS

Embodiments provide an array substrate of a liquid crystal display for decreasing haze that is generated by gas that is used in a gate insulating layer deposition process, and that reacts with a transparent conductive material when an electrode of a storage capacitor is made of the transparent conductive material, and a fabricating method thereof.

On aspect is a method of fabrication of an array substrate of a liquid crystal display, including: forming a gate electrode on a first region of a substrate, where the substrate is divided into first and second regions, forming a lower storage electrode, including a transparent conductive material, on the second region of the substrate, and forming a gate insulating layer on the substrate, where the gate insulating layer includes first, second and third gate insulating sub-layers.

Another aspect is an array substrate of a liquid crystal display, including, a substrate divided into a plurality of first regions and second regions, a plurality of gate electrodes formed on the first regions of the substrate, a lower storage electrode formed on the second regions of the substrate and made of a transparent conductive material, a gate insulating layer formed over the substrate, a semiconductor layer formed in a region corresponding with the gate electrodes, a plurality of source electrodes and a plurality of drain electrodes electrically connected to the semiconductor layer, and a pixel electrode electrically connected to the drain electrodes and formed on regions corresponding with the lower storage electrodes, where the gate insulating layer has a tiered structure including first, second and third gate insulating sub-layers.

Another aspect is an array substrate of a liquid crystal display, including, a substrate, a plurality of gate electrodes formed on the substrate of a first material, a lower storage electrode formed on the substrate and made of a transparent conductive material, a gate insulating layer formed over the substrate, where the gate insulating layer has a tiered structure including first, second and third gate insulating sub-layers, where the sub-layers are made of a same material, a semiconductor layer formed in a region corresponding with the gate electrodes, a plurality of source electrodes and a plurality of drain electrodes electrically connected to the semiconductor layer, and a pixel electrode electrically connected to the drain electrodes and formed on regions corresponding with the lower storage electrodes, and a plurality of contact electrodes made of the first material, and formed in regions corresponding with the lower storage electrodes.

A triple layered gate insulating layer having different properties is formed on the transparent conductive material used as the lower electrode of the storage capacitor so that haze deterioration caused by the reaction between a gas used during the deposition process of the gate insulating layer and the transparent conductive material can be decreased.

### BRIEF DESCRIPTION OF THE DRAWINGS

The accompanying drawings, together with the specification, illustrate certain exemplary embodiments of the present invention.

FIG. 1 is a sectional view illustrating an embodiment of an array substrate of a liquid crystal display; and

FIGS. 2A to 2F are sectional views illustrating an embodiment of a method of fabrication of an embodiment of an array substrate of a liquid crystal display.

### DETAILED DESCRIPTION OF CERTAIN INVENTIVE EMBODIMENTS

In the following detailed description, certain exemplary embodiments have been shown and described, by way of illustration. As those skilled in the art would realize, the described embodiments may be modified in various ways, without departing from the spirit or scope of the present invention. Accordingly, the drawings and description are to be regarded as illustrative in nature and not restrictive. In addition, when an element is referred to as being “on” another element, it can be directly on the other element or be indirectly on the other element with one or more intervening elements interposed therebetween. Also, when an element is referred to as being “connected to” another element, it can be directly connected to the other element or be indirectly connected to the other element with one or more intervening elements interposed therebetween. Hereinafter, like reference numerals generally refer to like elements.

FIG. 1 is a sectional view illustrating an embodiment of an array substrate of a liquid crystal display. FIG. 1 shows only a region of a thin film transistor and a storage capacitor for the purpose of description.

Referring to FIG. 1, an embodiment of an array substrate of a liquid crystal display includes a transparent substrate 10 and a thin film transistor TFT and a storage capacitor Cst which are formed on the transparent substrate 10.

The thin film transistor TFT includes a gate electrode 12 formed on the transparent substrate 10, a gate insulating layer 18 formed on the gate electrode 12, a semiconductor layer 23 formed on the gate insulating layer 18, and a source electrode 26 and a drain electrode 28 that are formed on the semiconductor layer 23.

The gate electrode 12 is electrically connected to a gate line (not shown) and receives a gate signal from the gate line. The gate insulating layer 18 is formed on the gate electrode 12 and electrically insulates the gate electrode 12 from the source and drain electrodes 26 and 28.

The semiconductor layer 23 forms a conducting channel between the source electrode 26 and the drain electrode 28. The semiconductor layer 23 includes an active layer 20, and an ohmic connecting layer 22 formed between the active layer 20 and the source/drain electrodes 26 and 28. The active layer 20 may be made of an amorphous silicon on which impurities are not coated, and the ohmic connecting layer 22 may be made of an amorphous silicon coated with N- or P-type impurities. The semiconductor layer 23 supplies a voltage to the source electrode 26 and the drain electrode 28 when a gate signal is supplied to the gate electrode 12.

The storage capacitor Cst is formed by a lower storage electrode 30 and a pixel electrode 42 serving as an upper storage electrode. The gate insulating layer 18 and a protecting layer 38 serve as dielectrics therebetween.

A contact hole 40 is formed at a position corresponding to the drain electrode 28. The pixel electrode 42 may be electrically connected to the drain electrode 28 via the contact hole 40.

The lower storage electrode 30 may be formed of a transparent conductive material, on the same layer as the gate electrode. In some embodiments, the lower storage electrode 30 may be made of indium tin oxide (ITO), tin oxide (TO), indium zinc oxide (IZO), indium tin zinc oxide (ITZO) and the like.

In the embodiment of FIG. 1, a contact electrode 12′, made of the same material as that of the gate electrode 12, is formed in a region overlapped with the lower storage electrode 30. The contact electrode 12′ may prevent the storage capacitor Cst from being floated, when a predetermined static voltage is applied to the contact electrode 12′. In other embodiments, the use of the contact electrode 12′ is optional.

Each of the storage capacitors Cst in respective pixel regions of an embodiment of the liquid crystal display may be made transparent in the above-described structure such that an aperture ratio of the liquid crystal display can be maximized.

If a transparent conductive material is used as the lower storage electrode 30, the gate insulating layer 18 formed on the lower storage electrode 30 and/or gas used in the deposition of the semiconductor layer 23 may react with the transparent conductive material to generate unwanted haze.

In general, the gate insulating layer 18 and the semiconductor layer 23 are formed by plasma-enhanced chemical vapor deposition (PECVD). When a reduction reaction gas (such as, for example, N₂, NH₃, SiH₄ and the like) is used as a reaction gas for the deposition process, the production of hydrogen (H) radicals is increased by the reduction reaction gas, and oxide forming the lower storage electrode 30 is reduced, and because of these two phenomena, that haze is generated.

In some embodiments, the gate insulating layer 18 is formed as a triple layer structure, with each sub-layer having different properties. In the embodiment of FIG. 1, the gate insulating layer includes a first, second and third gate insulating sub-layers 18a, 18b, and 18c. Such a layered structure may help to overcome the haze generated by the lower storage electrode 30 in the initial formation of the gate insulating layer 18 and/or the semiconductor layer 23 on the storage electrode 30.

The first, second and third gate insulating sub-layers 18a, 18b, and 18c forming the gate insulating layer 18 may be made of silicon nitride (SiNx). The properties of the sub-layers 18a, 18b and 18c may be different from each other due to the deposition rate and the flow of gas used in the respective deposition processes.

In some embodiments, the same deposition rate may be applied to the first and third gate insulating sub-layers 18a and 18c, and a different deposition rate may be applied to the second gate insulating sub-layer 18b.

In some embodiments, the deposition rate applied to the first and third gate insulating sub-layers 18a and 18c may be smaller than that applied to the second gate insulating sub-layer 18b.

In some embodiments, the flow of the reduction reaction gas (such as N₂, NH₃, SiH₄ and the like) used in the deposition process of the first and third gate insulating sub-layers 18a and 18c may be smaller than the flow of the reduction reaction gas used in the deposition process of the second gate insulating sub-layer 18b.

In one embodiment, the first gate insulating sub-layer 18a may contact the lower storage electrode 30, NH₃ gas may not be used in the deposition process, and the flow of SiH₄ may be smaller than that of the third gate insulating sub-layer 18c.

In some embodiments, the differences in the properties of the first and third gate insulating sub-layers 18a and 18c and the second gate insulating sub-layer 18b may be as listed in Table 1.

TABLE 1

| | | First & third gate | Second insulating |
|---|---|---|---|
| | | insulating sub-layers | sub-layer |
| Deposition rate | | 1630 | 1240 |
| (Å/min) | | | |
| Gas | N₂ | 4,000 | 10,000 |
| Flow | NH₃ | 1,600 | 1,500 |
| (sccm) | SiH₄ | 360 | 250 |

In one embodiment, the first gate insulating sub-layer 18a contacting the lower storage electrode 30 may be deposited by a process in which the flow of SiH₄ may be smaller than the flow of SiH₄ used to deposit the third gate insulating sub-layer 18c, and NH₃ gas may not be used. In such an embodiment, generation of H radicals caused by the reduction gas is restricted, thereby preventing the haze deterioration due to the reduction reaction with the oxide contained in the transparent conductive material as the lower storage electrode 30.

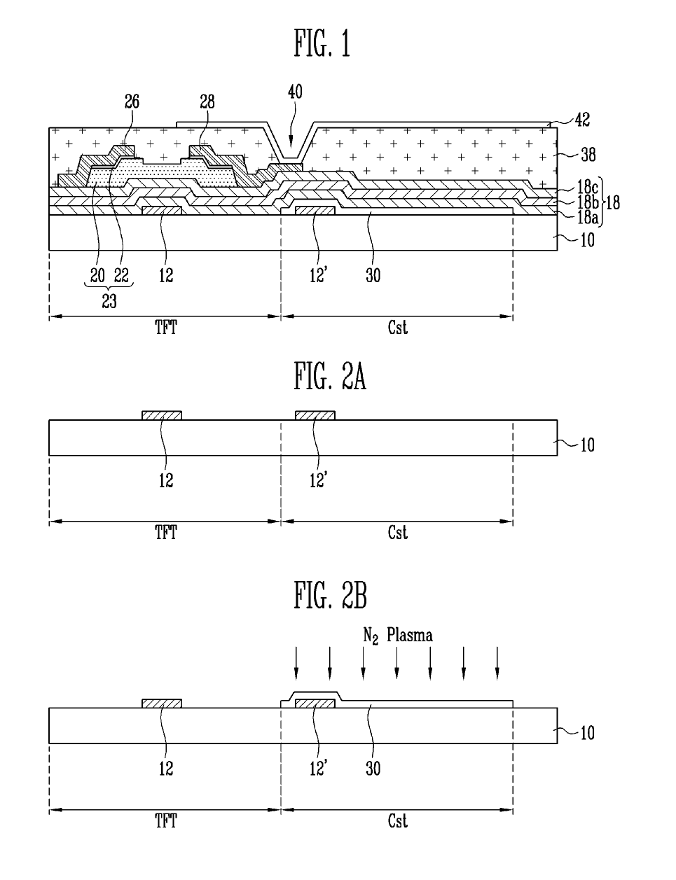

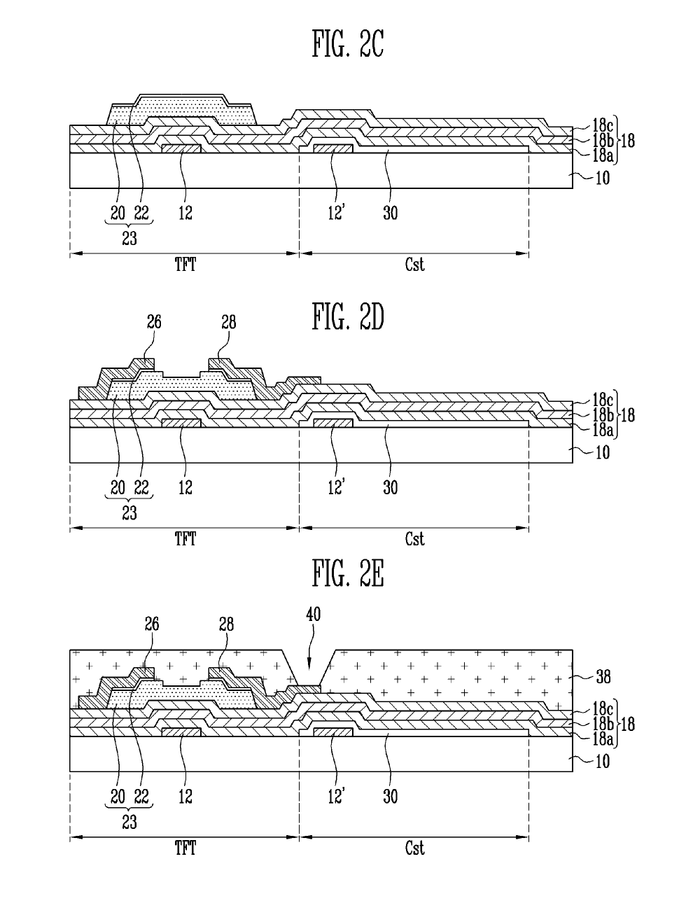

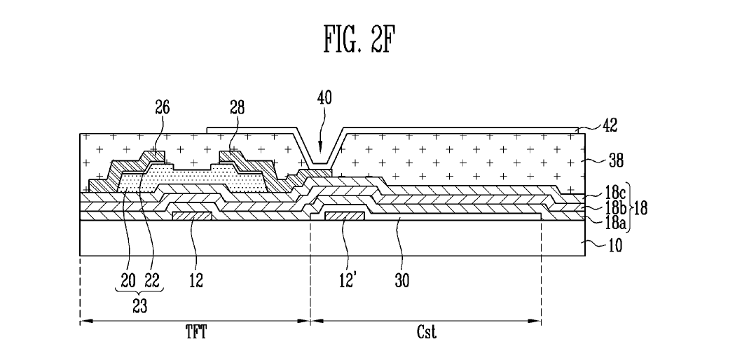

FIGS. 2A to 2F are sectional views illustrating an embodiment of a method of fabrication of an embodiment of an array substrate of a liquid crystal display.

Referring to FIG. 2A, the gate electrode 12 is formed in a thin film transistor (TFT) forming region on the transparent substrate 10. The gate electrode 12 is laminated on the lower substrate 10 by a deposition method such as a sputtering method. In some embodiments, the gate electrode 12 may be made of aluminum (Al), molybdenum (Mo), chrome (Cr), and copper (Cu).

In some embodiments, the contact electrode 12′, formed of the same material as the gate electrode 12 may be formed in a storage capacitor Cst forming region on the transparent substrate 10. The contact electrode 12′ may be overlapped with and be electrically connected to a partial region of the lower storage electrode 30 formed in the storage capacitor Cst, and may prevent the storage capacitor Cst from being floated when a predetermined static voltage is applied to the contact electrode 12′.

Referring to FIG. 2B, the lower storage electrode 30 is formed in the storage capacitor Cst forming region on the lower substrate 10 by a deposition method. In some embodiments, the lower storage electrode 30 may be made of a transparent conductive material such as ITO, TO, IZO, ITZO and the like.

In one embodiment, an N₂ plasma process may be performed to an upper surface of the lower storage electrode 30. Such a process may control generation of H radicals due to the reduction gas that is produced during the deposition process of the gate insulating layer (not shown) formed on the lower storage electrode 30. Thus, haze deterioration, generated by the reduction between H radicals and the oxide of the lower storage electrode, may be further enhanced.

Referring to FIG. 2C, the gate insulating layer 18 is formed on the transparent substrate 10 and the semiconductor layer 23, including the active layer 20 and the ohmic contact layer 22, is formed in the thin film transistor TFT forming region.

In some embodiments, the gate insulating layer 18 may be formed on the lower substrate 10 by a deposition method, such as plasma enhanced chemical vapor deposition (PECVD), and may include a first, second and third gate insulating sub-layers 18a, 18b, and 18c, each sub-layer having different properties.

In some embodiments, the first, second and third gate insulating sub-layers 18a, 18b, and 18c forming the gate insulating layer 18 may all be formed of silicon nitride (SiNₓ). The gate insulating sub-layers 18a, 18b and 18c may have different deposition rates and flow of gases used in their deposition process.

In one embodiment, the same deposition rate may be applied to the first and third gate insulating sub-layers 18a and 18c, and a different deposition rate may be applied to the second gate insulating layer 18b.

In one embodiment, the deposition rate applied to the first and third gate insulating layers 18a and 18c may be smaller than the rate applied to the second gate insulating layer 18b.

In some embodiments, the flow of the reduction reaction gas (such as N₂, NH₃, SiH₄ and the like) used in the deposition process of the first and third gate insulating sub-layers 18a and 18c may be smaller than the flow of the reduction reaction gas used in the deposition process of the second gate insulating sub-layer 18b.

In one embodiment, the first gate insulating sub-layer 18a may contact the lower storage electrode 30, NH₃ gas may not be used in the deposition process, and the flow of SiH₄ may be smaller than that of the third gate insulating sub-layer 18c. The generation of H radicals caused by the reduction gas is thus restricted, thereby preventing the haze deterioration due to the reduction reaction with the oxide contained in the transparent conductive material used in the lower storage electrode 30.

In addition to forming the gate insulating layer 18, an amorphous silicon layer, and an amorphous silicon layer coated with impurities are formed. The amorphous silicon layer and the amorphous silicon layer coated with impurities are both patterned using a photolithography process and an etching process to form the semiconductor layer 23, including the active layer 20 and the ohmic contact layer 22.

Next, referring to FIG. 2D, the source electrode 26 and the drain electrode 28 are formed by a deposition method such as sputtering, and the like. The source electrode 26 and the drain electrode 28 may be formed by depositing metal (for example, molybdenum (Mo), molybdenum tungsten (MoW) and the like), and by being patterned by a photolithography process and an etching process. The ohmic contact layer 22 exposed between the source electrode 26 and the drain electrode 28 may be removed by using the source electrode 26 and the drain electrode 28 as a mask when exposing the active layer 20.

Referring to FIG. 2E, a protecting layer 38 may be formed to cover the source electrode 26, the drain electrode 28. The protecting layer 38 may be formed by a method such as PECVD, spin coating, spinless coating and the like. A contact hole 40 may be formed by patterning the protecting layer 38 by a photolithography process and an etching process. The contact hole 40 may be formed at a position corresponding to the drain electrode 28. The protecting layer 38 may be made of an inorganic insulating material such as the material used to form the gate insulating layer 18 and the like, or of an organic material such as acryl and the like.

Referring to FIG. 2F, the pixel electrode 42 is formed on the protecting layer 38. The pixel electrode 42 may be formed by a deposition method such as sputtering and the like. The pixel electrode 42 may be electrically connected to the drain electrode 28 via the contact hole 40 and may serve as the upper storage electrode.

The storage capacitor Cst may thus be formed by the lower storage electrode 30 and the pixel electrode 42, serving as the upper storage electrode, and the gate insulating layer 18 and the protecting layer 38 serving as dielectrics therebetween. The pixel electrode 42 may be made of a transparent conductive material such as ITO, TO, IZO, ITZO and the like.

With the pixel electrode 42 (upper storage electrode) and the lower storage electrode 30 being made of a transparent conductive material, the area between the two electrodes may be widened regardless of the aperture ratio. Therefore, a high capacitance storage capacitor Cst may be formed, and driving reliability may thus be enhanced and a high aperture ratio may be achieved.

While the present invention has been described in connection with certain exemplary embodiments, it is to be understood that the invention is not limited to the disclosed embodiments, but, on the contrary, is intended to cover various modifications and equivalent arrangements included within the spirit and scope of the invention.

What is claimed is:

1. A method of fabrication of an array substrate of a liquid crystal display, comprising:
forming a gate electrode on a first region of a substrate, wherein the substrate is divided into first and second regions;
forming a lower storage electrode, comprising a transparent conductive material, on the second region of the substrate; and
forming a gate insulating layer on the substrate;
wherein the gate insulating layer comprises first, second and third gate insulating sub-layers.

2. The method of fabrication of claim 1, further comprising:
forming a semiconductor layer in a region overlapping the gate electrode;
forming a source electrode and a drain electrode, configured to be electrically connected to the semiconductor layer; and
forming a pixel electrode in a region overlapping the lower storage electrode and electrically connected to the drain electrode.

3. The method of fabrication of claim 1, wherein the first, second and third gate insulating sub-layers are formed of a same material and by application of different deposition rates and flows of gases during a deposition process.

4. The method of fabrication of claim 3, wherein a deposition rate applied to the first gate insulating sub-layer is substantially the same as a deposition rate applied to the third gate insulating sub-layers and is different than a deposition rate applied to the second gate insulating sub-layer.

5. The method of fabrication of claim 4, wherein the deposition rate applied to the first and third gate insulating sub-layers is lower than the deposition rate applied to the second gate insulating sub-layer.

6. The method of fabrication of claim 3, wherein a flow of reduction reaction gas used in the deposition process of the first and third gate insulating sub-layers is lower than a flow of a reduction reaction gas used in the deposition process of the second gate insulating sub-layer.

7. The method of fabrication of claim 6, wherein the reduction reaction gas comprises at least one of NH₃ and SiH₄.

8. The method of fabrication of claim 6, wherein the first gate insulating sub-layer is deposited by a flow of SiH₄ gas lower than the flow of gas used to deposit the third gate insulating sub-layer.

9. The method of fabrication of claim 2, wherein the lower storage electrode and the pixel electrode are formed with at least one of indium tin oxide (ITO), tin oxide (TO), indium zinc oxide (IZO), and indium tin zinc oxide (ITZO).

10. The method of fabrication of claim 1, further comprising forming a contact electrode formed of the same material as the material of the gate electrode in regions corresponding with the lower storage electrodes.

11. An array substrate of a liquid crystal display, comprising;
a substrate divided into a plurality of first regions and second regions;
a plurality of gate electrodes formed on the first regions of the substrate;
a lower storage electrode formed on the second regions of the substrate and made of a transparent conductive material;
a gate insulating layer formed over the substrate;
a semiconductor layer formed in a region corresponding with the gate electrodes;
a plurality of source electrodes and a plurality of drain electrodes electrically connected to the semiconductor layer; and
a pixel electrode electrically connected to the drain electrodes and formed on regions corresponding with the lower storage electrodes;
wherein the gate insulating layer has a tiered structure comprising first, second and third gate insulating sub-layers.

12. The array substrate of claim 11, wherein the first, second and third gate insulating sub-layers are made of a same material and are formed by application of different deposition rates and flow of gases during a deposition process.

13. The array substrate of claim 11, wherein the lower storage electrodes and the pixel electrodes are formed with one of indium tin oxide (ITO), tin oxide (TO), indium zinc oxide (IZO), and indium tin zinc oxide (ITZO).

14. The array substrate of claim 11, further comprising contact electrodes made of the same material as the material of the gate electrodes, and formed in regions corresponding with the lower storage electrodes.

15. An array substrate of a liquid crystal display, comprising;
a substrate;
a plurality of gate electrodes formed on the substrate of a first material;
a lower storage electrode formed on the substrate and made of a transparent conductive material;
a gate insulating layer formed over the substrate, wherein the gate insulating layer has a tiered structure comprising first, second and third gate insulating sub-layers, wherein the sub-layers are made of a same material;
a semiconductor layer formed in a region corresponding with the gate electrodes;
a plurality of source electrodes and a plurality of drain electrodes electrically connected to the semiconductor layer; and
a pixel electrode electrically connected to the drain electrodes and formed on regions corresponding with the lower storage electrodes; and
a plurality of contact electrodes made of the first material, and formed in regions corresponding with the lower storage electrodes.

16. The array substrate of claim 15, wherein the gate insulating sub-layers are formed by application of different deposition rates and flow of gases during a deposition process.

17. The array substrate of claim 15, wherein the lower storage electrode and the pixel electrode are each formed with at least one of indium tin oxide (ITO), tin oxide (TO), indium zinc oxide (IZO), and indium tin zinc oxide (ITZO).

18. The array substrate of claim 15, wherein the gate insulating layer is configured to function as a dielectric.

19. The array substrate of claim 18, wherein the pixel electrode is configured to function as an upper storage electrode in a storage capacitor formed by the pixel electrode, the lower storage electrode and the gate insulating layer formed therebetween.
